(19) United States
(12) Patent Application Publication
(10) Pub. No.: US 2017/0370973 A1
(43) Pub. Date: Dec. 28, 2017

(54) SENSOR MODULE

(71) Applicant: DENSO CORPORATION, Kariya-city (JP)

(72) Inventors: Masamichi ITO, Kariya-city (JP); Kazuki MIKAMO, Kariya-city (JP)

(21) Appl. No.: 15/619,641

(22) Filed: Jun. 12, 2017

(30) Foreign Application Priority Data
Jun. 27, 2016 (JP) 2016-126752

(51) Int. Cl. G01R 19/165; G01R 31/28; G01R 23/02; G01R 31/3181; G01R 19/00

(52) U.S. Cl. CPC G01R 19/16552; G01R 31/3181; G01R 19/0084; G01R 23/02; G01R 31/282

(57) ABSTRACT

A circuit chip is connected to a sensor chip in a sub-unit via a communication terminal, and includes an output wave formation circuit that performs communication by controlling a voltage of a power supply supplied from an electronic control unit (ECU) to raise a voltage level of an output signal. When the voltage of the power supply monitored by a voltage monitor rises above a threshold value, a control circuit lowers a voltage of a signal from the output wave formation circuit, thereby preventing an excessive rise of the power supply voltage used in a signal communication.

### CROSS REFERENCE TO RELATED APPLICATION

The present application is based on and claims the benefit of priority of Japanese Patent Application No. 2016-126752, filed on Jun. 27, 2016, the disclosure of which is incorporated herein by reference.

### TECHNICAL FIELD

The present disclosure generally relates to a sensor module that has a sensor section including a sensor and a communicator communicating with the sensor section connected via a communication terminal.

### BACKGROUND INFORMATION

Conventionally, to reduce the module size of a sensor module having a sensor chip and other integrated circuits (ICs), chip to chip communication (i.e., inter-chip communication between the sensor chip and other ICs) uses a pull-up logic communication signal. That is, the communication line “pulls up” the communication line of the chips (e.g., sensor chip and other IC) to be at the same voltage level as the power supply line, thereby putting the communication signal at a high level or high state, i.e., at a higher voltage.

A protection element in the IC, such as a clamper, is often used for a clamping operation when a power supply to a ground line exceeds certain voltage thresholds. ICs often have other elements and features that operate at voltages exceeding the voltage threshold limited by the clamper. However, the clamper does not protect against a voltage rise to all of the other elements and features running at voltages higher than the voltage threshold, as limited by the clamper.

The patent document 1 listed below discloses, while not providing discussion about an excessive voltage protection, a protection operation for protecting electric components from abnormality of an electric current in a power supply line that is used for an electric current driven type communication.

(Patent document 1) Japanese Patent No. 5799914

In contrast to the other ICs in a sensor module, a sensor chip and its elements often operate at voltages lower than the voltage threshold, as limited by the protection elements in the other ICs. As such, an excessive rise of voltage to the power supply of the sensor module in turn causes a voltage rise to the other components in the other ICs, and subsequently this higher voltage can be transmitted via the communication line to the sensor chip, thereby exceeding the voltage level of the sensor chip, resulting in damage or breakage of the sensor chip.

While current circuit protection works as intended, improved circuit protection is needed.

### SUMMARY

It is an object of the present disclosure to provide a sensor module that protects a sensor section in the sensor module against an excessive rise of a power supply voltage that is used as a communication signal.

In one or other aspect of the present disclosure, a communicator in the sensor module may be connected to a sensor section via a communication terminal, and has a signal outputter that performs communication by controlling a voltage of a power supply that comes from an outside of the sensor module to raise a voltage level of an output signal. Further, when the voltage of the power supply monitored by a voltage monitor rises above a preset upper limit value, a sensor protector in the communicator performs a protection operation, which either (i) lowers the voltage level of the output signal from the signal outputter or (ii) interrupts an electric connection of the communication terminal. According to such configuration, even when the voltage of the power supply exceeds a voltage threshold, the higher voltage from the power supply does not affect the sensor section via the communication terminal of the communicator. Therefore, the sensor section is securely protected from higher power supply voltage levels.

### BRIEF DESCRIPTION OF THE DRAWINGS

Objects, features, and advantages of the present disclosure will become more apparent from the following detailed description made with reference to the accompanying drawings, in which:

FIG. 1 illustrates a block diagram of a sensor module in a first embodiment of the present disclosure;

FIG. 2 illustrates a circuit diagram of an output wave formation circuit;

FIG. 3 illustrates a circuit diagram of a protection operation performed by a control circuit;

FIG. 4 illustrates a circuit diagram of an input wave reception circuit;

FIG. 5 illustrates a flowchart of an operation of the sensor module;

FIG. 6 illustrates a waveform of a process shown in FIG. 5;

FIG. 7 illustrates a circuit diagram of the output wave formation circuit in a second embodiment of the present disclosure;

FIG. 8 illustrates a circuit diagram of the output wave formation circuit in a third embodiment of the present disclosure;

FIG. 9 illustrates a flowchart of an operation of the sensor module in a fourth embodiment of the present disclosure;

FIG. 10 illustrates a block diagram of the sensor module in a fifth embodiment of the present disclosure; and

FIG. 11 illustrates a block diagram of the sensor module in a sixth embodiment of the present disclosure.

### DETAILED DESCRIPTION

### First Embodiment

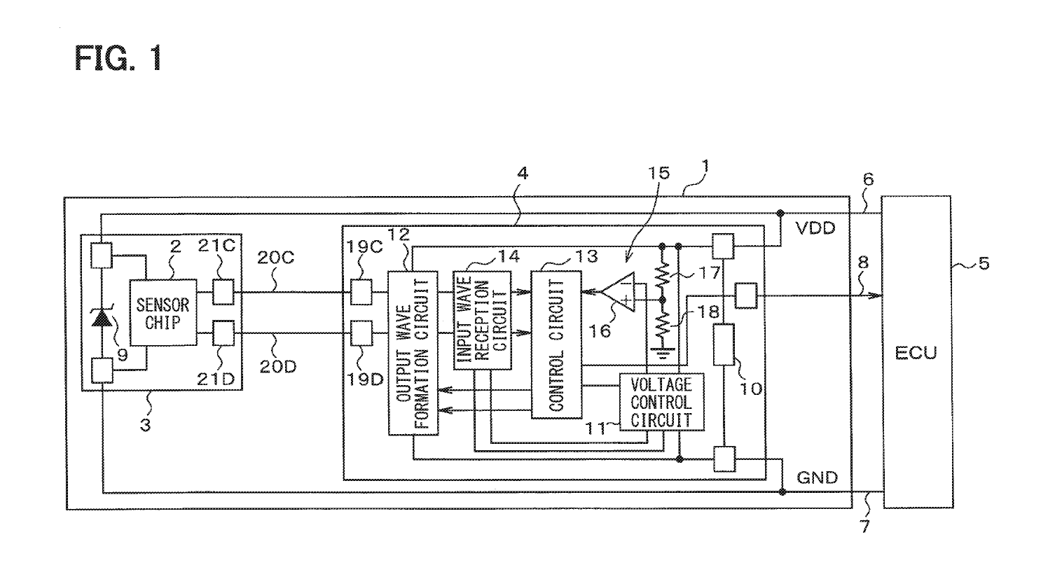

As shown in FIG. 1, a sensor module 1 in the first embodiment of the present disclosure includes (i) a sub-unit 3 having a sensor chip 2 and (ii) a circuit chip 4. As used herein, the sensor chip 2 may also be referred to as a “sensor section”, and the circuit chip 4 may also be referred to as a “communicator,” The sensor module 1 is connected to a high-level controller, for example, an ECU 5, via a power supply line 6, a ground line 7, and a signal line 8. That is, the sensor module 1 is provided with a power supply VDD of 5 V from the ECU 5, for example. The sub-unit 3 and the circuit chip 4 are respectively connected to the power supply line 6 and to the ground line 7. Protection element 9 in sensor chip 2 and protection element 10 in circuit chip 4 are also arranged respectively, in chips 2 and 4, at a position between the power supply line 6 and the ground line 7.

In the circuit chip 4, at a position between the power supply line 6 and the ground line 7, a voltage control circuit 1 and an output wave formation circuit 12 are connected. As used herein, tie output wave formation circuit 12 may also be referred to as a “signal outputter.” The voltage control circuit 11 is a regulator that steps-down the voltage from the ECU 5, to supply operational power to each of the elements in the circuit chip 4.

A control circuit 13 communicates with the sub-unit 3, for example, to transmit a signal to the sub-unit 3 via the output wave formation circuit 12. Further, the control circuit 13 may also receive sensor signal data from the sensor chip 2 via an input wave reception circuit 14. As used herein, the control circuit 13 may also be referred to as a “sensor protector.”

A voltage monitor circuit 15 is equipped with a comparator 16. At a position between the power supply line 6 and the ground line 7, a resistor 17 and a resistor 18 are provided in a series connection, i.e., the resistors 17 and 18 are connected in series, and a mid-point between the two resistors 17 and 18 is connected to a non-inverted input terminal, i.e., (V+), of the comparator 16. An inverted input terminal of the comparator 16, i.e., (V−), receives a threshold voltage generated by the voltage control circuit 11. An output terminal of the comparator 16 is connected to an input terminal of the control circuit 13. The threshold voltage may be an “upper limit” voltage value.”

The output wave formation circuit 12 is connected to a communications terminal 19C, and the input wave reception circuit 14 is connected to a communications terminal 19D. The communication terminals 19C, 190 are, respectively, connected to communication terminals 21C, 21D of sub-unit 3, via communication lines 20C, 20D. The communication between the sensor chip 2 and the circuit chip 4 is, for example, conducted by I²C® (Inter-Integrated Circuit) communication (alternatively I2C), in which a clock is transmitted via the communication terminal 19C, and data is transmitted via the communication terminal 190, respectively.

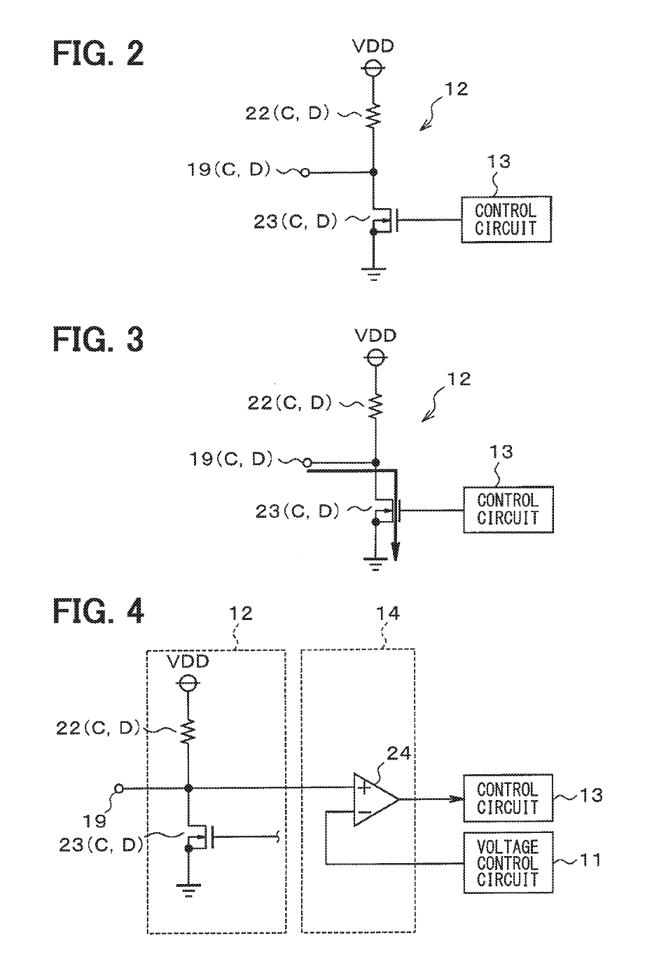

As shown in FIG. 2, the communication terminal 19 (C, D) is pulled up via a pull-up resistor 22 (C, D) to the power supply voltage VDD, while connected to the ground via an N-channel MOSFET 23 (C, D), i.e., Metal Oxide Semiconductor Field Effect Transistor, which may be abbreviated herein as “FET.” For brevity, a single pull-up resistor circuit is represented, but note that each pull-up resistor circuit would apply to respective communication terminals using like-designated reference characters. For example, the pull-up resistor circuit for communication terminal 19C would use pull-up resistor 22C and FET 23C, as shown in FIG. 2. Where a like-designated reference is not given, for example “FET 23”, this feature generally describes FET 23C and FET 23D. A gate of the FET 23 is connected to the output terminal of the control circuit 13, and the turning ON and OFF of the FET 23 is controlled by the control circuit 13. That is, the output wave formation circuit 12 forms an open-drain type output, in which a high-level communication signal from communication terminal 19 takes the power supply voltage VDD. The control circuit 13 transmits the clock and data to the sub-unit 3 by turning ON and OFF FETs 23C and 23D during normal communication.

As shown in FIG. 4, the input wave reception circuit 14 has a comparator 24, and a non-inverted input terminal, i.e., (V+), of the comparator 24 is connected to the communication terminal 19. An inverted input terminal, i.e. (V−), of the comparator 24 receives a reference voltage from the voltage control circuit 11, and an output terminal of the comparator 24 is connected to the input terminal of the control circuit 13. That is, the input wave reception circuit 14 receives the clock and data transmitted from the sensor chip 2 by using the comparator 24 to determine high-level and low-level communication signals, and outputs the clock and data to the control circuit 13. Further, a level of the communication signal transmitted from the control circuit 13 via the output wave formation circuit 12 can be monitored based on an output signal of the comparator 24.

The control circuit 13 may periodically transmit to the sensor chip 2 an output request for sensor data, and the sensor chip 2 in response may transmit, to the circuit chip 4, sensor data, i.e., data from the sensor. The control circuit 13 transmits received data, in the order received i.e., First In, First Out (“FIFO”), via the input wave reception circuit 14 to the ECU 5.

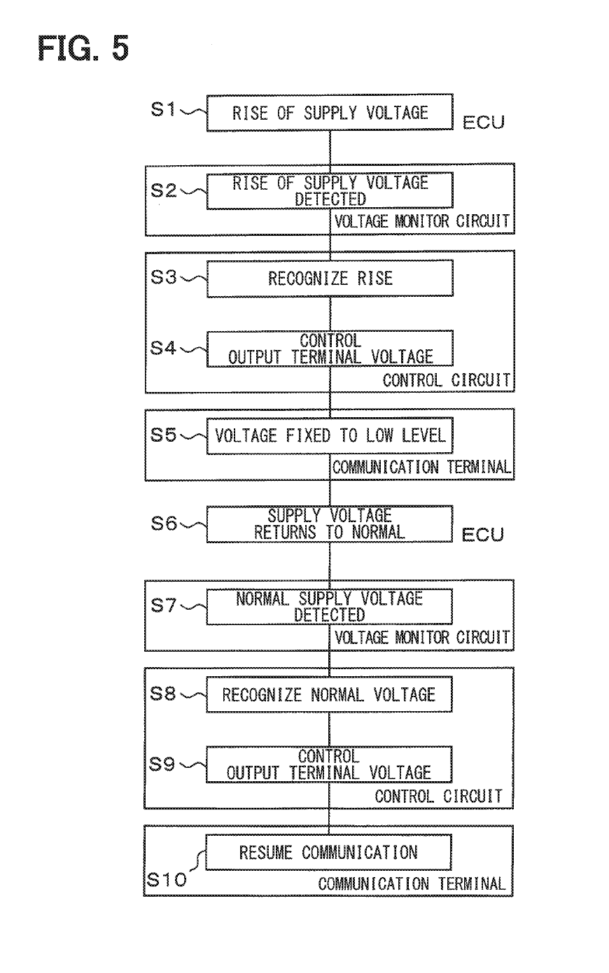

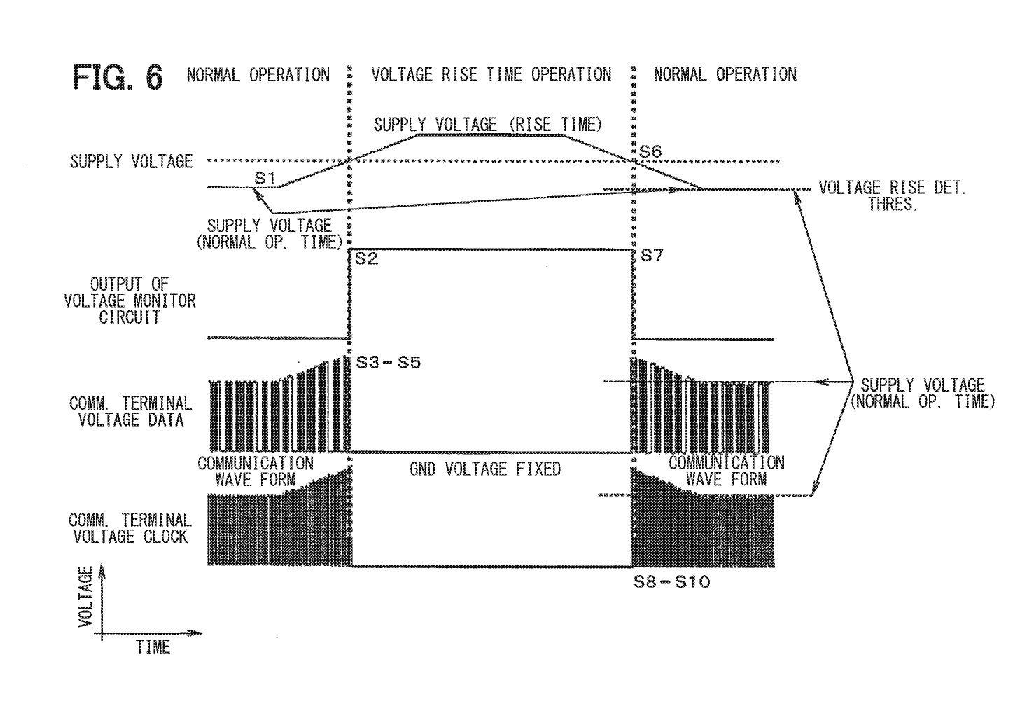

FIGS. 5 and 6 respectively illustrate and operational flow diagram and operational effects of the embodiment described above. When the circuit chip 4 communicates with the sub-unit 3, the voltage of the power supply VDD provided by the ECU 5 (i.e., SUPPLY VOLTAGE in FIG. 6) may start to rise for some unknown reasons (S1 in FIG. 5). Thereafter, when the voltage detected by the voltage monitor circuit 15 of the circuit chip 4 exceeds a threshold value, the voltage monitor circuit 15 outputs a high level output signal (S2). Then, the control circuit 13 recognizes the rise of the voltage (S3), and turns ON the FETs 23C and 230, as shown in FIG. 3 (S4), for keeping the voltage of the communication terminals 19C, 19D at a low level (S5). In such manner, the sensor chip 2 is protected from art excessive voltage.

At such a time when the voltage of the power supply VDD falls, and the voltage monitor circuit 15 detects a voltage that has fallen under the threshold voltage, i.e., the voltage has returned to normal (S6), the voltage monitor circuit 15 outputs a low-level output signal (S7). Thus, the control circuit 13 recognizes that the voltage has returned to normal (S8), and turns OFF the FETs 23C and 23D (59). Thereafter, the control circuit 13 turns ON the FETs 23C and 23D, accordingly, for resuming normal communication (S10). According to the present embodiment, the circuit chip 4 is provided with the output wave formation circuit 12 that (i) is connected to the sensor chip 2 in the sub-unit 3 via the communication terminals 19C, 190, and (ii) communicates by a signal in response to a high power supply (VDD) voltage level from the ECU 5.

When the voltage of the power supply VDD monitored by the voltage monitor circuit 15 rises above a threshold value, the control circuit 13 instructs the output wave formation circuit 12 to output a low-level output signal. In such configuration, the excessive rise of the power supply VDD voltage from the ECU 5 is prevented from affecting the sensor chip 2 via the communication terminals 19C, 19D. Accordingly, the sensor chip 2 is protected from excessive voltage.

### Second and Third Embodiments

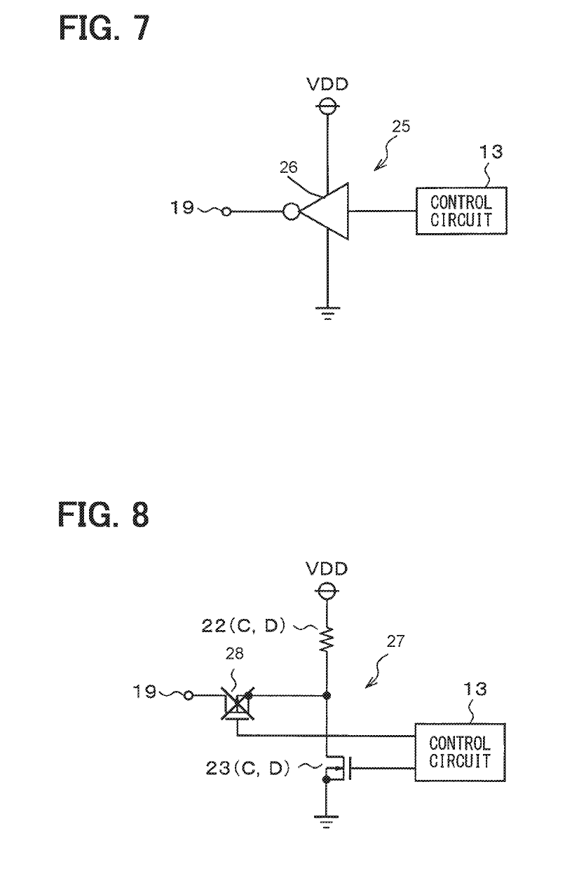

Other configurations of the output wave formation circuit are shown in the second and third embodiments of the present disclosure. FIG. 7 illustrates an output wave formation circuit 25 of the second embodiment, in which an inverter gate 26 is used instead of a FET, for example FET 23 shown in FIG. 2. In such configuration, the control circuit 13 inputting the high level signal in step S5 of FIG. 5 may protect the sensor chip 2 by lowering the voltage levels at the communication terminal 19.

An output wave formation circuit 27 in FIG. 8 of the third embodiment has a P-channel MOSFET 28 added to the configuration of the first embodiment, with a source of the FET 28 connected to the drain of the FET 23, a drain of the FET 28 connected to the communication terminal 19, and a gate of the FET 28 connected the output terminal of the control circuit 13. In such case, when the control circuit 13 inputs a high-level signal as a process corresponding to step S5 of FIG. 5 to turn OFF the FET 28, a state shown by a sign “X” on FET 28 in FIG. 8, the electric connection between the resistor 22 and the communication terminal 19 is interrupted. In such manner, the sensor chip 2 is protected from an excessive voltage.

### Fourth Embodiment

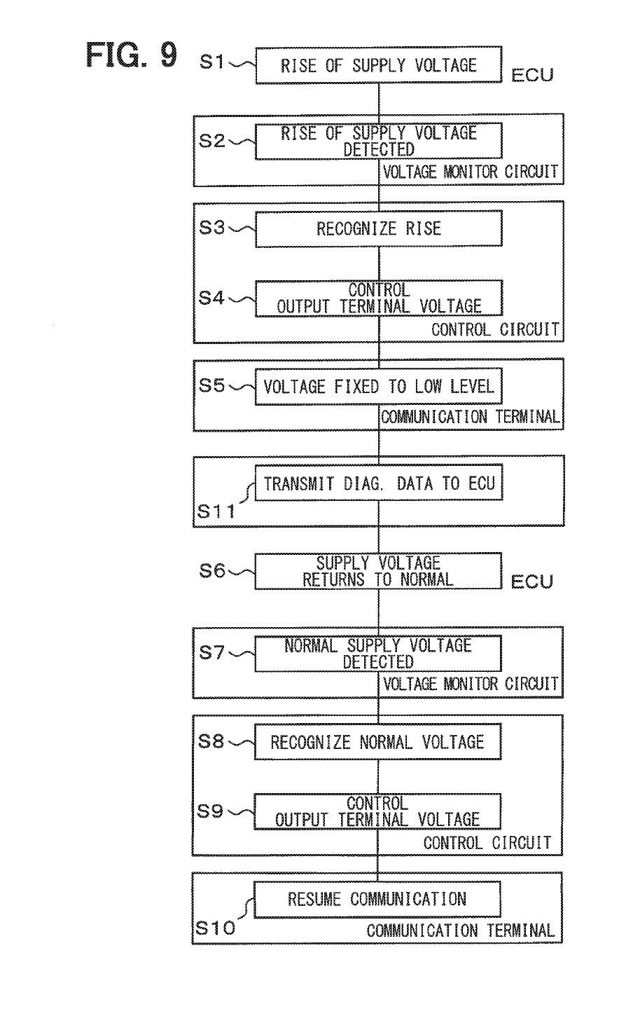

The fourth embodiment shown in FIG. 9 has the control circuit 13, which transmits a diagnosis data to the ECU 5 in step S11, after performing step S5 of FIG. 5. In such manner, ECU 5 is notified of the excessive rise of the power is supply (VDD) voltage as supplied by the ECU 5. The diagnosis data is a predetermined data that is configured to have a specific data value, i.e., a value different from a normal sensor data, and used by the control circuit 13 to diagnosis excessive power supply (VDD) voltage levels as supplied by the ECU 5.

### Fifth Embodiment

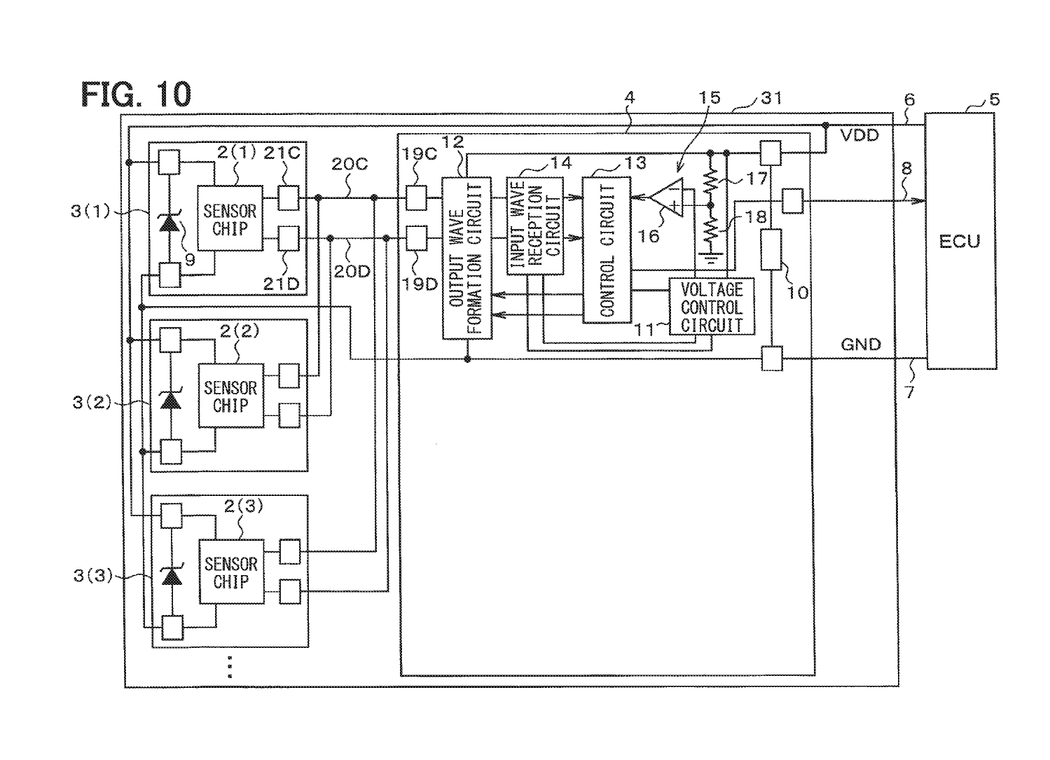

The fifth embodiment shown in FIG. 10 has a sensor module 31, that is provided with a plurality of sub-units 3(1), 3(2), 3(3), . . . and the like, respectively in connection with the communication terminals 19C, 19D of the circuit chip 4.

In such case, the control circuit 13 receives data from each of sensor chips 2(1), 2(2), 2(3), . . . and the like, by multiplexing, for example, in a time-division manner, by addressing those chips 2(1), 2(2), 2(3) . . . in the sub-units 3(1), 3(2), 3(3) . . . , respectively.

### Sixth Embodiment

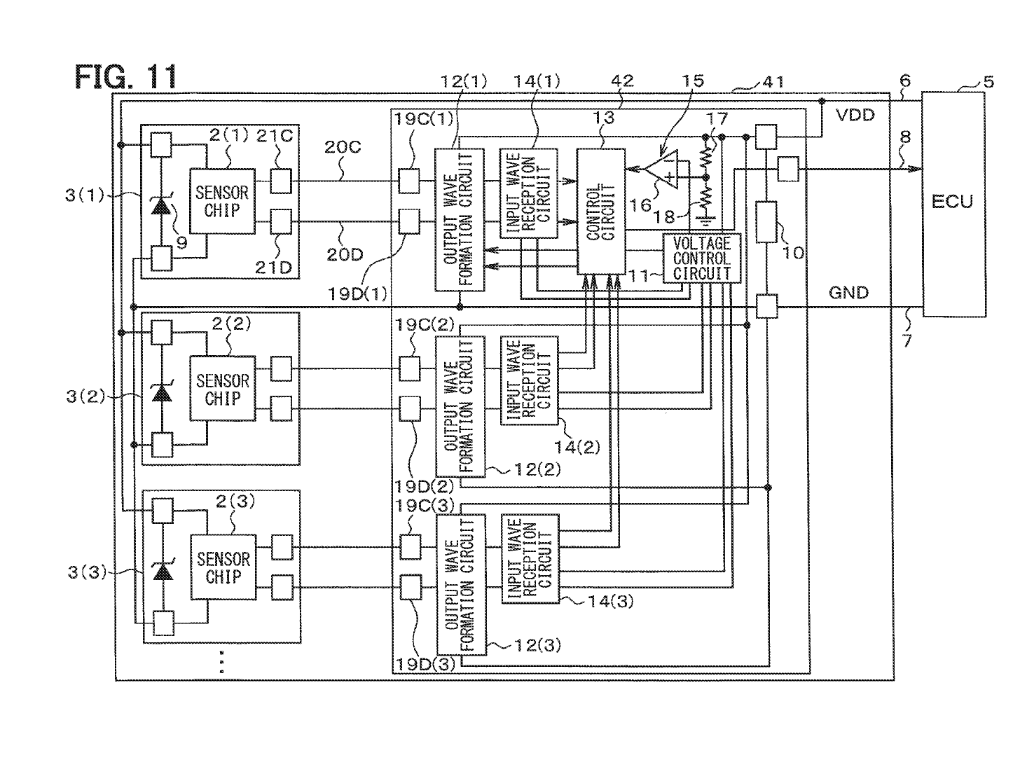

The sixth embodiment in FIG. 11 has a sensor module 41 which is provided with the plurality of sub-units 3(1), 3(2), 3(3), . . . and the like, just like the fifth embodiment. Further, a circuit chip 42 is equipped with the output wave formation circuit 12, the input wave reception circuit 14, and the communication terminals 19C, 19D for each of the plurality of sub-units 3(1), 3(2), 3(3), . . . and the like.

In such case, the control circuit 13 selectively uses, corresponding to each of the sub-units 3(1), 3(2), 3(3) . . . , the output wave formation circuits 12(1, 2, 3, . . . ), the input wave reception circuits 14(1, 2, 3, . . . ), and the communication terminals 19C(1, 2, 3, . . . ), 19D(1, 2, 3, . . . ), for performing communication.

The communication may be performed, for example, in a time-division manner, as described in the fifth embodiment, or may be performed, for example, in parallel, by providing a buffer in the control circuit 13 for data reception and for storage of received data in parallel.

Although the present disclosure has been fully described in connection with preferred embodiments thereof with reference to the accompanying drawings, it is to be noted that various changes and modifications will become apparent to those skilled in the art.

For example, the communication standard may be not only limited to the I2C standard, but also be based on other standards. Further, the number of the communication terminals may be other than “2”.

The power supply voltage may be arbitrarily changed according to the design of each of the various configurations.

The sensor may be a sensor with a sensor function other than a humidity sensing.

The above embodiments may be combinable with each other. The high-level controller may be other than the ECU 5, i.e., may be provided as a microcomputer, a CPU or the like, to be serving as a master or a host, for example.

Such changes, modifications, and summarized schemes are to be understood as being within the scope of the present disclosure as defined by appended claims.

What is claimed is:

1. A sensor module comprising:
a sensor section having a sensor and a communication interface that outputs a sensor signal from the sensor to an outside of the sensor section; and
a communicator connected to the sensor section via a communication terminal and having a signal outputter that performs communication by controlling a voltage of a power supply from an outside of the sensor module to raise a voltage level of an output signal, wherein
the communicator includes:
a voltage monitor monitoring the voltage of the power supply; and
a sensor protector protecting the sensor by performing a protection operation that lowers a voltage level of the output signal of the signal outputter upon detecting a power supply voltage exceeding an upper limit value.

2. A sensor module comprising:
a sensor section having a sensor and a communication interface that outputs a sensor signal from the sensor to an outside of the sensor section; and
a communicator connected to the sensor section via a communication terminal and having a signal outputter that performs communication by controlling a voltage of the power supply from an outside of the sensor module to raise a voltage level of the output signal, wherein
the communicator includes:
a voltage monitor monitoring the voltage of the power supply; and
a sensor protector protecting the sensor by performing a protection operation that interrupts an electric connection of the communication terminal upon detecting a power supply voltage exceeding an upper limit value.

3. The sensor module of claim 1, wherein
the communicator transmits, to a high-level controller,
(i) the sensor signal received from the sensor section, and
(ii) an abnormal signal as an abnormality notification upon detecting that the sensor protector has performed the protection operation.
